(19) United States
(12) Patent Application Publication
(10) Pub. No.: US 2026/0099647 A1
(43) Pub. Date: Apr. 9, 2026

(54) PROVIDING AND TRAINING A SIMULATION MODEL OF A THREE-DIMENSIONAL PRINTER

(71) Applicant: INTERNATIONAL BUSINESS MACHINES CORPORATION, Armonk, NY (US)

(72) Inventors: Daniel Thomas Cunnington, Boulder, CO (US); Jonah Benjamin Michael Luckett, Derby (GB); Gwilym Benjamin Lee Newton, Winchester (GB); Elizabeth Jane Maple, Basingstoke (GB)

(21) Appl. No.: 18/933,314

(22) Filed: Oct. 31, 2024

(30) Foreign Application Priority Data
Oct. 3, 2024 (GB) 2414555.9

(51) Int. Cl. G06F 30/27; G06F 30/17

(52) U.S. Cl. CPC G06F 30/27; G06F 30/17

(57) ABSTRACT

A method, machine learning model, and computer system are provided for simulation of a three-dimensional (3D) printer. An aspect of the method predicts the 3D printer output and provides feedback by: obtaining, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file; comparing the input 3D geometry file and the output 3D geometry file from the simulation model to determine differences; and displaying a representation of the differences to a user.

### BACKGROUND

The present invention relates to three-dimensional printer modeling, and more specifically, to simulation of a three-dimensional printer for input design feedback.

Three-dimensional (3D) printers have revolutionized the area of additive manufacturing. Users design 3D models using a 3D modelling tool, where they can theoretically create any 3D structure. However, there are many 3D structures that can be designed but cannot be printed using a 3D printer. There are also many 3D structures that can be designed but a 3D printer would struggle to print, or the design may only be printed by the most advanced and most precise printers available. There is therefore a set of hidden challenges and constraints at design time, as the user must design 3D models that are likely to print reliably using the printer(s) they have access to.

Many models may be possible to print but require a high level of user skill to obtain successful results. As a result, there is often an expensive trial-and-error process whereby the user attempts to print their model, inspects the result, makes design changes, and re-prints, etc. These constraints can be highly complex and specific to the printer or the environment. For example, a certain printer may not be able to print with enough precision to correctly produce detailed aspects of a model or mechanical instabilities in the print head may ultimately impact the quality of the printed object.

### SUMMARY

According to an aspect of the present invention there is provided a computer-implemented method for training a simulation model of a three-dimensional (3D) printer, said method comprising: obtaining training input data as an input 3D geometry file as input into the 3D printer; obtaining training output data by converting a 3D print output of the 3D printer generated in response to the input 3D geometry file into an output 3D geometry file of a same file type as the input 3D geometry file and aligning the output 3D geometry file and the input 3D geometry file; and constructing a training dataset entry of the combined training input data and training output data for training the simulation model of the 3D printer.

The method for training a simulation model of a 3D printer has the advantage of training the model based on input 3D geometry files and the actual output object of the 3D printer converted into a 3D geometry file. This captures the areas of poor performance of the printer when printing the input file.

Converting of a 3D print output may include photogrammetry conversion of photographs of the 3D print output into an output 3D geometry file. This may give an accurate conversion of the 3D print output.

The output 3D geometry file may be of a different resolution to the input 3D geometry file and the training dataset may be provided for training the simulation model to output the higher resolution 3D geometry file. This accommodates the conversion process used for converting the 3D print object.

The method may include obtaining printer parameters and/or user parameters for a printing process generating the 3D print output and including the printer parameters and/or user parameters in the training dataset.

According to an aspect of the present invention there is provided a computer-implemented method for modelling simulation of a three-dimensional (3D) printer, said method comprising: providing a trained simulation model for a 3D printer for simulating variations in printing parameters and their effect on the 3D printer output; inputting an input 3D geometry file into the trained simulation model; modeling an embedding representation of the input 3D geometry file; modeling the printer parameters to output learned embedding; concatenating the input embedding and the learned embedding; and outputting an output 3D geometry file aligned to the input 3D geometry file.

This method for modelling simulation of a 3D printer has the advantage of simulating the output of the 3D printer in response to a 3D geometry file input by a user at the design stage. This results in an output of indications of areas of the input file that will be problematic in the printing process before the expensive printing is carried out.

The trained simulation model may be a graph neural network (GNN) and the method may include: encoding the input 3D geometry file using a GNN encoder; modeling the printer parameters using multi-layer perception to output learned embedding; and decoding the output 3D geometry file using a GNN decoder.

The method may include training the simulation model for a 3D printer with training dataset entries of combined training input data and training output data, wherein: the training input data is obtained as an input 3D geometry file as input into the 3D printer; and the training output data is obtained by converting a 3D print output of the 3D printer generated in response to the input 3D geometry file into an output 3D geometry file of a same file type as the input 3D geometry file and aligning the output 3D geometry file and the input 3D geometry file.

The output 3D geometry file may be of a higher resolution than the input 3D geometry file based on the training output data in the training datasets. A resolution may be input as a hyper-parameter of the simulation model.

According to an aspect of the present invention there is provided a computer-implemented method for predicting a three-dimensional (3D) printer output, said method comprising: obtaining, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file; comparing the input 3D geometry file and the output 3D geometry file from the simulation model to determine differences; and displaying a representation of the differences to a user.

The method for predicting a 3D printer output displays a representation of the differences between the 3D geometry input file and the output 3D geometry file from the model giving an indication of the areas of problematic printing before the printing is undertaken.

The output 3D geometry file may be of a different resolution to the input 3D geometry file, and the method may include converting the input 3D geometry file into a software-generated resolution 3D geometry file of the same resolution as the output 3D geometry file.

Comparing the input 3D geometry file and the output 3D geometry file may include computing a difference between distances of sampled vertices in the aligned input 3D geometry file and the output 3D geometry file. The method may include converting the computed distances into a heat-map representation by assigning colors to distances.

The method may include providing a trained simulation model for a 3D printer for simulating variations in printing parameters and their effect on the 3D printer output; and inputting an input 3D geometry file into the simulation model.

The method may include training the simulation model for a 3D printer with training dataset entries of combined training input data and training output data, wherein: the training input data is obtained as an input 3D geometry file as input into the 3D printer; and the training output data is obtained by converting a 3D print output of the 3D printer generated in response to the input 3D geometry file into an output 3D geometry file of a same file type as the input 3D geometry file and aligning the output 3D geometry file and the input 3D geometry file.

According to an aspect of the present invention there is provided a trained simulation model for modelling simulation of a three-dimensional (3D) printer, comprising: an encoder for receiving an input 3D geometry file into the trained simulation model; a first embedding vector component for embedding a representation of the input 3D geometry file; a modeling component for receiving printer parameters; a second embedding vector component for embedding the learned printer parameters; a joint embedding vector component for concatenating the input embedding and the learned embedding; and a decoder for outputting an output 3D geometry file aligned to the input 3D geometry file.

The trained simulation model may be a graph neural network (GNN) and wherein: the encoder is a GNN encoder; the modeling component for receiving printer parameters is for modeling the printer parameters using multi-layer perception to output learned embedding; and the decoder is a GNN decoder.

According to an aspect of the present invention there is provided a system for predicting a 3D printer output, comprising: a processor and a memory configured to provide computer program instructions to the processor to execute a method of: obtaining, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file; comparing the input 3D geometry file and the output 3D geometry file from the simulation model to determine differences; and displaying a representation of the differences to a user.

The output 3D geometry file may be of a different resolution to the input 3D geometry file, and the method may include converting the input 3D geometry file into a software-generated resolution 3D geometry file of the same resolution as the output 3D geometry file.

Comparing the input 3D geometry file and the output 3D geometry file may include: computing a difference between distances of sampled vertices in the aligned input 3D geometry file and the output 3D geometry file; and converting the computed distances into a heat-map representation by assigning colors to distances.

The method may include: providing a simulation model for a 3D printer for simulating variations in printing parameters and their effect on the 3D printer output; training the simulation model for a 3D printer with training dataset entries of combined training input data and training output data, wherein: the training input data is obtained as an input 3D geometry file as input into the 3D printer; and the training output data is obtained by converting a 3D print output of the 3D printer generated in response to the input 3D geometry file into an output 3D geometry file of a same file type as the input 3D geometry file and aligning the output 3D geometry file and the input 3D geometry file.

Converting of a 3D print output may include photogrammetry conversion of photographs of the 3D print output into an output 3D geometry file.

The method may include obtaining printer parameters and/or user parameters for a printing process generating the 3D print output and including the printer parameters and/or user parameters in the training dataset.

According to an aspect of the present invention there is provided a computer program product for training a simulation model of a three-dimensional (3D) printer, the computer program product comprising a computer readable storage medium having program instructions embodied therewith, the program instructions executable by a processor to cause the processor to: obtain training input data as an input 3D geometry file as input into the 3D printer; obtain training output data by converting a 3D print output of the 3D printer generated in response to the input 3D geometry file into an output 3D geometry file of a same file type as the input 3D geometry file and aligning the output 3D geometry file and the input 3D geometry file; and construct a training dataset entry of the combined training input data and training output data for training the simulation model of the 3D printer.

According to an aspect of the present invention there is provided a computer program product for modelling simulation of a three-dimensional (3D) printer, the computer program product comprising a computer readable storage medium having program instructions embodied therewith, the program instructions executable by a processor to cause the processor to: provide a trained simulation model for a 3D printer for simulating variations in printing parameters and their effect on the 3D printer output; input an input 3D geometry file into the trained simulation model; model an embedding representation of the input 3D geometry file; model the printer parameters to output learned embedding; concatenate the input embedding and the learned embedding; and output an output 3D geometry file aligned to the input 3D geometry file.

According to an aspect of the present invention there is provided a computer program product for predicting a three-dimensional (3D) printer output, the computer program product comprising a computer readable storage medium having program instructions embodied therewith, the program instructions executable by a processor to cause the processor to: obtain, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file; compare the input 3D geometry file and the output 3D geometry file from the simulation model to determine differences; and display a representation of the differences to a user.

The computer readable storage medium may be a non-transitory computer readable storage medium and the computer readable program code may be executable by a processing circuit.

The present invention seeks to provide one or more concepts for training, modelling, and providing designer feedback using simulation of a 3D printer. Such concepts may be computer-implemented. That is, such methods may be implemented in a computer infrastructure having computer executable code tangibly embodied on a computer readable storage medium having programming instructions configured to perform a proposed method. The present invention further seeks to provide a computer program product including computer program code for implementing the proposed concepts when executed on a processor.

### BRIEF DESCRIPTION OF THE DRAWINGS

Embodiments of the present invention will now be described, by way of example only, with reference to the accompanying drawings:

FIG. 1 is a flow diagram of an example embodiment of aspects of a method in accordance with embodiments of the present invention;

FIG. 2 is a schematic diagram of an example embodiment of aspects of the described method and system;

FIG. 3 is a block diagram of an example embodiment of a machine learning model in accordance with embodiments of the present invention;

FIG. 4 is a flow diagram of an example embodiment of a training method in accordance with embodiments of the present invention;

FIG. 5 is a flow diagram of an example embodiment of a modeling method in accordance with embodiments of the present invention;

FIGS. 6A and 6B are diagrams showing a representation of a geometrical input file and a representation of a higher resolution geometrical output file;

FIG. 6C is a diagram showing a heat map as an example representation of the feedback to the designer;

FIG. 7 is a block diagram of an example embodiment of a system in accordance with embodiments of the present invention; and

FIG. 8 is a block diagram of an example embodiment of a computing environment for the execution of at least some of the computer code involved in performing the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION

Embodiments of a method, system, and computer program product are provided for providing and training a simulation model of a 3D printer. The disclosure predicts a likely output of a 3D printer for a 3D geometry file input into the 3D printer. A 3D geometry file may be generated by a 3D modeling software and may be a file defining the geometry of a 3D surface. For example, a 3D geometry file may be a stereolithography file, such as an STL file format, in which a surface geometry of a 3D object is described as a triangulated surface using a 3D coordinate system. Other 3D geometry file formats may be used such as an OBJ file format or a BLEND file format. The 3D geometry file may be referred to as a build file as it is used to build the 3D object using the 3D printer.

The simulation model of a 3D printer is provided using machine learning. In the described embodiments a graph neural network (GNN) is used. In other embodiments a non-graph neural network may be used. The simulation model may be provided for a specific printer by providing printer parameters in the model. The simulation model may be specific to a user's printer and operating conditions and therefore may also be trained for user parameters, or it may be shared across multiple users with the same make and model of printer where only printer parameters are required.

Once trained, the simulation model can take as input, an input 3D geometry file and simulate the 3D printer by generating an output in the form of a 3D render of what the printed output would look like. This output may then be compared to the input file to generate a representation that indicates the likelihood of each region being printed successfully. The representation may be provided as feedback to the designer who can then inspect the areas in which an unsuccessful print is likely and adjust their model accordingly. The representation may be visualized in 3D printing design software, indicating potential failure regions. This has the advantage of providing feedback to the designer who may make adjustments to the design of the input build file until it falls within the bounds of the capabilities of the printer and where the likelihood of obtaining a successful print is high.

The method predicts potential problem areas of a 3D printed object using a trained machine learning algorithm. It does this by looking at the entirety of the object as well as the previous performance of the printer when printing similar shapes, rather than just looking at individual layers. Therefore, the disclosure is a holistic solution to the prediction of issues when printing 3D printed objects.

The simulation of a 3D printer is an improvement in the technical field of 3D printing and design input to 3D printers.

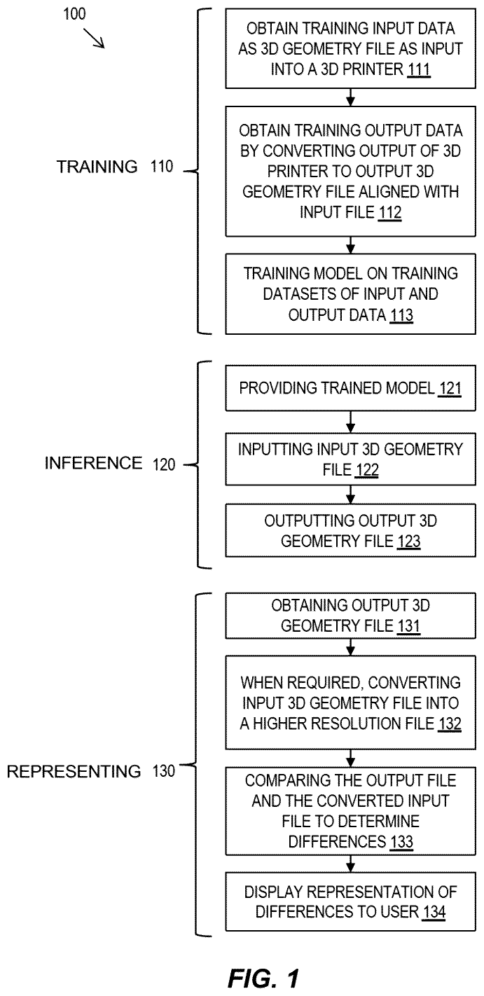

Referring to FIG. 1, a flow diagram 100 shows an example embodiment of the described aspects of the method. A first aspect 110 is the training of the simulation model of a 3D printer. A second aspect 120 is the inference carried out by the simulation model of the 3D printer. The third aspect 130 is the feedback representation to a designer using the output of the simulation model.

The first aspect 110 for training a simulation model of a 3D printer includes obtaining 111 training input data in the form of an input 3D geometry file as input into the 3D printer during use of the 3D printer.

The first aspect 110 for training a simulation model of a 3D printer includes obtaining 112 training output data by converting a 3D print output of the 3D printer generated in response to the input 3D geometry file into an output 3D geometry file of the same file type as the input 3D geometry file and aligning the output 3D geometry file and the input 3D geometry file. The output 3D geometry file may be of the same of a different resolution than the input 3D geometry file. In one embodiment, the output 3D geometry file is of a higher resolution due to a conversion method from the printer output.

The first aspect 110 trains the simulation model using the constructed training datasets of the training input data and corresponding training output data. The simulation model is configured for a type of printer by using printer parameters in the model learning processing for predicting their effect on the 3D printer output.

The second aspect 120 is the inference carried out by the simulation model of the 3D printer. The second aspect 120 includes providing 121 a trained simulation model for the 3D printer for simulating variations in printing parameters and their effect on the 3D printer output.

During inference, the method inputs 122 an input 3D geometry file into the trained simulation model and outputs 123 an output 3D geometry file of the same file type as the input 3D geometry file. The output 3D geometry file may be of the same or a different resolution than the input 3D geometry file according to the training data of the training output file format.

The modeling processes the input 3D geometry file in the simulation model for simulating variations in printing parameters and their effect on the 3D printer output. The modeling includes modeling an embedding representation of the input 3D geometry file and modeling the printer parameters using multi-layer perception to output learned embedding; and concatenating the input embedding and the learned embedding to produce the output. Further details of the modeling are given below.

The third aspect 130 of providing a feedback representation to a designer includes obtaining 131 an output 3D geometry file of a same file type as the input 3D geometry file. The output 3D geometry file may be of the same or a different resolution than the input 3D geometry file.

When the output 3D geometry file is of a different resolution than the input 3D geometry file, the method of the third aspect 130 converts 132 the input 3D geometry file (as input into the simulation model to obtain the output) into a software-generated 3D geometry file of the same resolution as the output file.

The method of the third aspect 130 compares the input 3D geometry file or a software generated resolution-matching file and the output 3D geometry file from the simulation model to determine differences. The method of the third aspect 130 displays 134 a representation of the differences to the designer.

The designer may adapt their 3D geometry file based on the feedback and the method may loop to input the adapted build file into the model at step 122 of the second aspect 120 to obtain an updated output build file for further analysis by the third aspect 130.

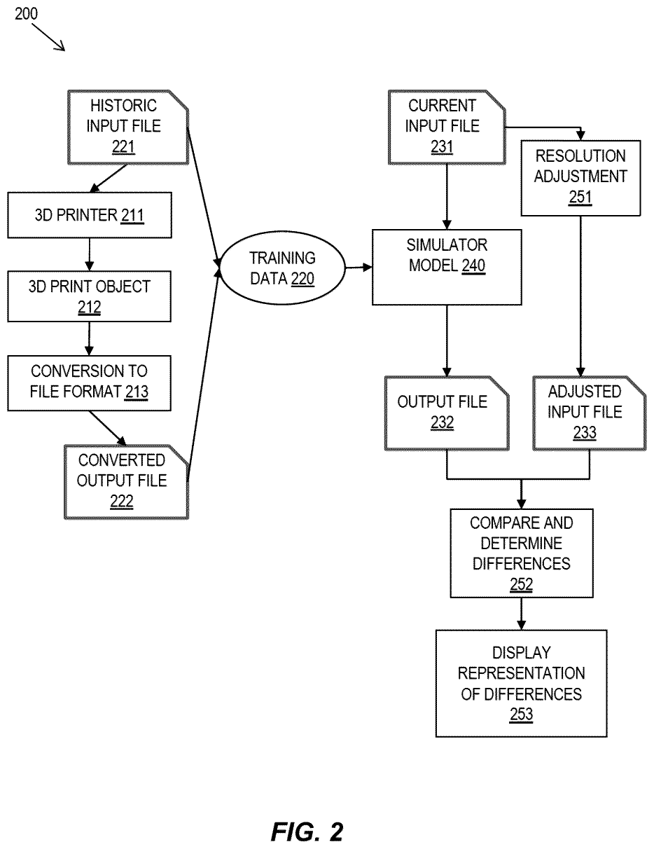

Referring to FIG. 2, a schematic diagram 200 illustrates the flow of the overall system. All the input and output files are of a same file type in the form of a 3D geometry file type.

Training data is obtained by using historic input files 221 as input into a 3D printer 211 (i.e., in the form of actual 3D geometry files that have be input into the 3D printer) to output a 3D print object 212. A conversion process 213 is carried out to convert the 3D print object 212 into a converted output file 222 of the same file type as the historic input file 221. The conversion process 213 may use photogrammetry to obtain a 2D image of the 3D print object 212 and to provide the 2D image as the converted output file 222. An alternative to photogrammetry may be 3D modeling with highly accurate measurements to obtain a 2D image of the 3D print object 212 and to provide the 2D image as the converted output file 222. The historic input file 221 and the corresponding converted output file 222 together provide training data 220 to a 3D printer simulator model 240. The training data may also include printer parameters and/or user parameters for a printing process generating the 3D print object 212.

In an inference process, the simulator model 240 has a current input file 231 and outputs an output file 232. The current input file 231 has a resolution adjustment 251 carried out, if needed, to result in an adjusted input file 233. This is needed if the converted output file 222 of the training process is of a different resolution to the historic input file 221 resulting in the output file 232 of the simulator model also being of a different resolution to the input file 231. A feedback process compares 252 the output file 232 of the simulator model 240 with the adjusted input file 233 (or the original input file if no adjustment is needed) and determines differences in the files. The feedback process outputs a display representation of the differences to a designer so that the designer can apply the feedback to the current input file 231.

### Model Architecture

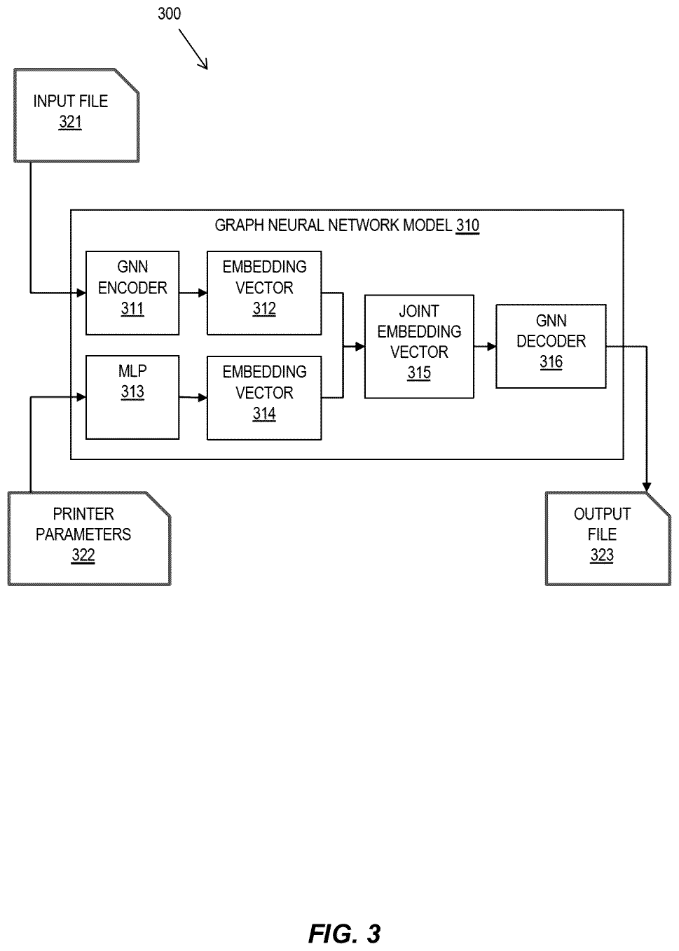

Referring to FIG. 3, a block diagram 300 shows an example embodiment of a machine learning component used for simulation of a 3D printer. In the described embodiment, a neural network is used, specifically, a Graph Neural Network (GNN) 310, to learn a simulated model of a 3D printer. Once trained and during inference, the neural network can quickly produce a likely output representation of a 3D object, given an input model at design time.

A GNN 310 may be selected because a 3D geometry input file 321 can be represented as a set of nodes and edges and therefore is suitable for a graph representation and learning mechanism.

GNNs use pairwise message passing, such that graph nodes iteratively update their representations by exchanging information with their neighbors. The architecture of a generic GNN implements the following fundamental layers. Permutation equivariant: a permutation equivariant layer maps a representation of a graph into an updated representation of the same graph. Permutation equivariant layers are implemented via pairwise message passing between graph nodes. Intuitively, in a message passing layer, nodes update their representations by aggregating the messages received from their immediate neighbors. As such, each message passing layer increases the receptive field of the GNN by one hop. Local pooling: a local pooling layer coarsens the graph via down sampling. Local pooling is used to increase the receptive field of a GNN, in a similar fashion to pooling layers in convolutional neural networks. Global pooling: a global pooling layer, also known as readout layer, provides fixed-size representation of the whole graph. The global pooling layer must be permutation invariant, such that permutations in the ordering of graph nodes and edges do not alter the final output.

The GNN 310 receives as input an input 3D geometry file 321 and outputs a 3D geometry file 323. The GNN 310 includes a GNN encoder 311 that receives the input 3D geometry file 321 and is connected to an embedding vector 312. The GNN 310 includes a Multi-Layer Perceptron (MLP) 313 that has as input printer parameters 322 for the 3D printer. The MLP 313 is connected to an embedding vector 314 that outputs a learned embedding. The outputs of the two embedding vectors 312, 314 are concatenated by a joint embedding vector 315 and passed to a GNN decoder 316. The GNN decoder 316 outputs a 3D geometry file 323 of the same file type as the input 3D geometry file.

The GNN 310 may be trained for each make and model of 3D printer. This may be provided with fine-tuning add-ons that enable the neural network to be adjusted to suit the individual needs and environment of the end-user.

As input, the neural network expects a build file 321 exported at design time from standard 3D modelling software. This is fed through the GNN encoder 311, to learn an embedding representation of the input file geometry.

Printer and/or user parameters are captured and fed into the GNN 310 using the MLP 313 for each training. The printer and user parameters may include layer height, print head temperature, bed temperature, axis speed, fill percentage, fill type, etc. The MLP 313 outputs a learned embedding which is concatenated with the embedding from the GNN encoder 311. This enables the neural network to capture variations in printing parameters and learn how these affect the resulting output.

The GNN decoder 316 produces the desired output representation, which may be a “dense” 3D geometry file 323. The density is a resolution and can be chosen as a hyper-parameter by a user. The motivation for choosing a dense output representation may be due to a method of obtaining the training data which is described below.

In a specific example, the input 3D geometry file 321 may be an STL file and the output dense 3D geometry file 323 may be a dense STL file referred to as “STL-D”. By dense, it is meant an increased number of triangles in the file per unit volume than the input STL.

### Training

For training, a dataset of expected inputs and outputs is constructed. In terms of representation, the method is based on an input file format that is used by design software for generating an input file for a 3D printer. For example, this may be a 3D geometry file that describes a surface geometry of a 3D object. For example, the industry standard STL file may be used that contains a series of linked triangles (a graph) that describes the surface geometry of a 3D object. The training output is the same file format but may have a different resolution.

The method of obtaining the training dataset enables automatic, crowd-sourced collection from 3D printers and thus adds technical feasibility. A 3D printer manufacturer may facilitate collection of the training data by providing collection software that may reside in software located either within the printer itself, or on a computer (such as a small computer, for example, a Raspberry Pi (registered trademark)) attached to the printer. The training data may be built up over time by observing input files and output objects.

Firstly, the input build file as created by upstream modelling/slicing software is stored. Secondly, the resulting 3D print is converted to a two-dimensional representation and aligned to the input to produce a converted output build file of the same file format as the input build file. The converted output build file may be of a different resolution to the input build file. The inputs and output are stored as one entry in a database for training. This process is repeated many times with many objects until a large dataset is obtained.

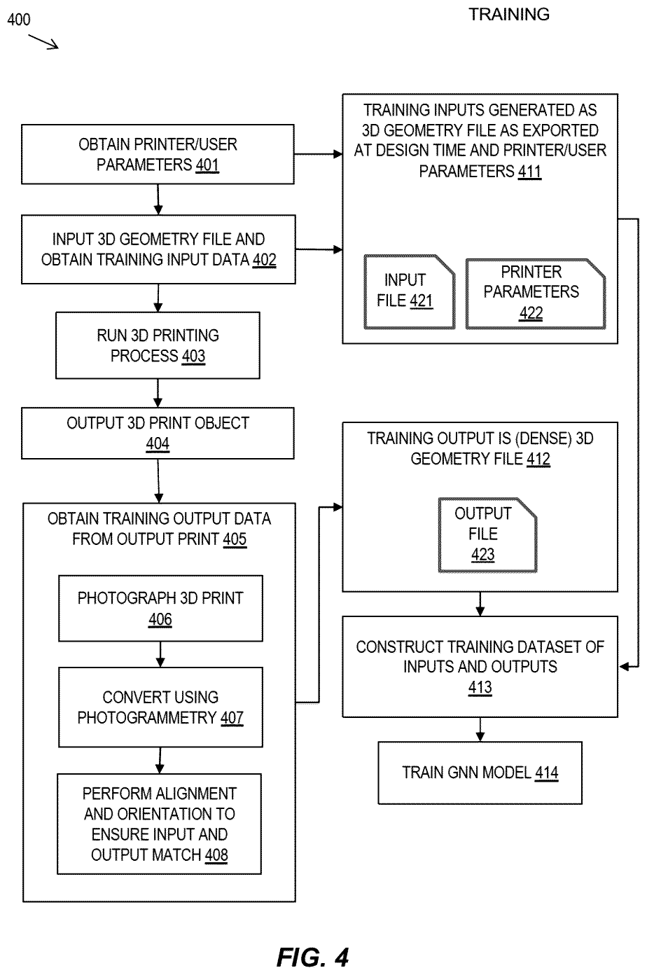

Referring to FIG. 4, a flow diagram 400 shows an example embodiment of a method of training a simulation model of a 3D printer.

Printer parameters of a 3D printer are obtained 401 and an input build file is input 402 into the 3D printer and a 3D printing process is run 403 to output a 3D print object 404. Training inputs are generated 411 as the printer parameters 422 of the 3D printer and the input build file 421.

The output of the 3D printer is processed to provide 412 a suitable training output. The 3D print object 404 may be converted to two dimensions using photogrammetry or 3D modeling using scanning.

The 2D output produced by the conversion may be a higher resolution dense build file 423 than the input build file. Output training data is obtained 405 in this way from the output 3D print of the 3D printer.

In one embodiment, the output training data is obtained 405 by photographing 406 the resulting 3D print, using multiple cameras. The photographs are converted 407 by running photogrammetry software to produce a dense build file of the same file format as the input build file. For example, the photogrammetry step may convert imagery into a dense 3D STL representation.

This conversion is followed by an alignment stage, to produce a dense representation. An alignment stage (using translation, rotation, and reflection) is carried out to ensure the x, y, and z dimensions of the input and output representations match. This consists of a set of linear transformations applied to the output in order to align it and orient it with the input. This can be achieved by minimizing the distance between a sampled set of triangle vertices in each model, or through more advanced methods.

The inputs and output are then provided as one entry in a database for constructing 413 training datasets. This process is repeated many times with many objects until a large training dataset is obtained.

The simulation model is trained 414 on the characteristics of the printer and the previous shapes it has had issues with so that it is able to perform predictions before an item is sent to the 3D printer, or has ever been sent to the printer before, therefore saving time and materials.

### Inference and Representation

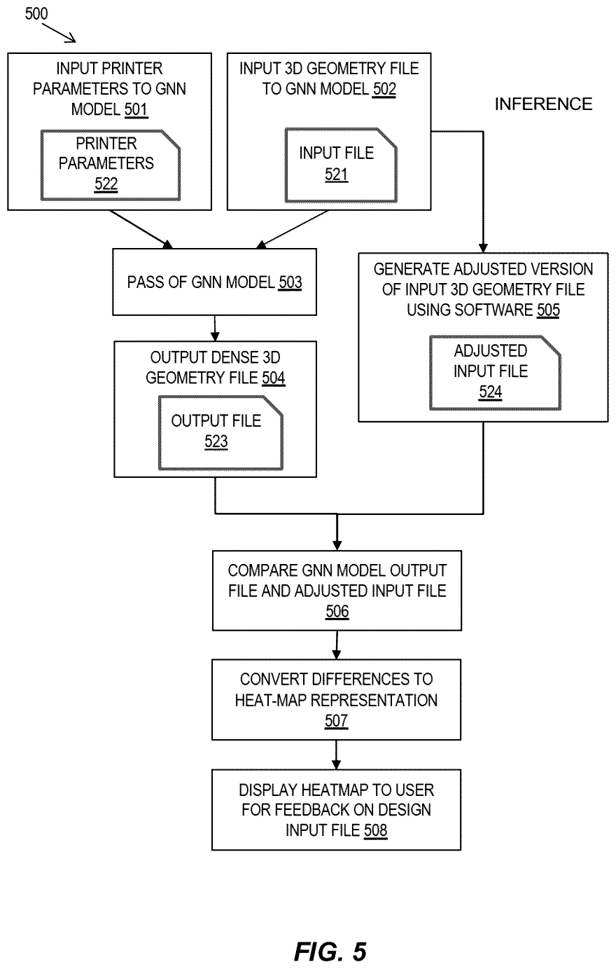

Referring to FIG. 5, a flow diagram 500 shows an example embodiment of an inference and feedback method using a 3D printer simulation model.

During inference, the goal is to use the trained GNN to produce a representation of likely failure areas during printing. To do so, a forward pass 501 of the neural network is run using an input 502 of the 3D geometry file 521 as currently designed and an input 501 of the current settings for the printer parameters 522. The GNN predicts an output 504 of a 3D geometry file 523.

The input build file 521 may processing to generate 505 an adjusted version of the input build file using software to provide an adjusted input build file 524 that matches the resolution of the output build file 523 of the GNN model 503.

The adjusted input build file and the output build file are compared 506 to create a representation of the differences. The representation may be a heat-map representation by converting 507 the differences to heat map representation. This may then be overlayed or displayed 508 to the user in 3D printing software.

A more specific example embodiment is described below. The input build file 521 may be an STL file representing the print object as currently designed using 3D printing software. This STL file, alongside current settings for printer parameters, are passed into the neural network. The GNN outputs a dense STL. This may be due to the training output being a dense STL due to the conversion of the training output from the 3D object. Therefore, a dense version of the input STL is generated using techniques such as software subdivide.

A difference between the GNN output dense STL file and the converted dense STL input file is generated, which can simply be a distance between a set of sampled vertices. The resolution as to how many vertices should be compared to can be configured by the user, for example, it may be all the vertices. It should be noted that as the neural network is trained to produce an aligned output dense STL, this comparison is possible.

This distance is then converted to a heat-map representation by assigning certain colors to large distances. Normalization may be applied to enable identification of a large vs small distance. The heat-map may then be displayed to the user using 3D printing software. The heat-map provided to the user at design time highlights any areas of the design that are likely to cause complications in the final print.

Using a trained neural network as opposed to a finite element analysis, results in inference being significantly faster, as a forward pass can simply be run through the network vs running a full simulation.

This enables the method to alert the user to issues and offer suggestions frequently during the design process.

The problem with prior art approaches is that it is often too late to correct a defect, and the user may have to restart the print. The described method occurs at design time before printing.

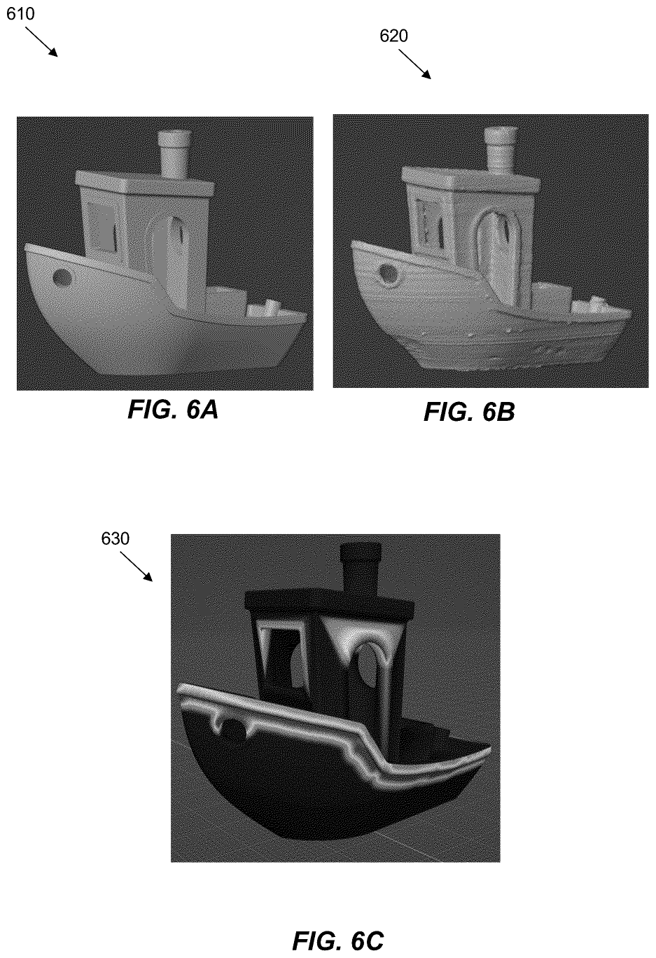

As illustration, FIG. 6A shows a representation of a geometrical input file and FIG. 6B shows a representation of a higher resolution geometrical output file. FIG. 6C is a diagram showing a heat map as an example representation of the feedback to the designer;

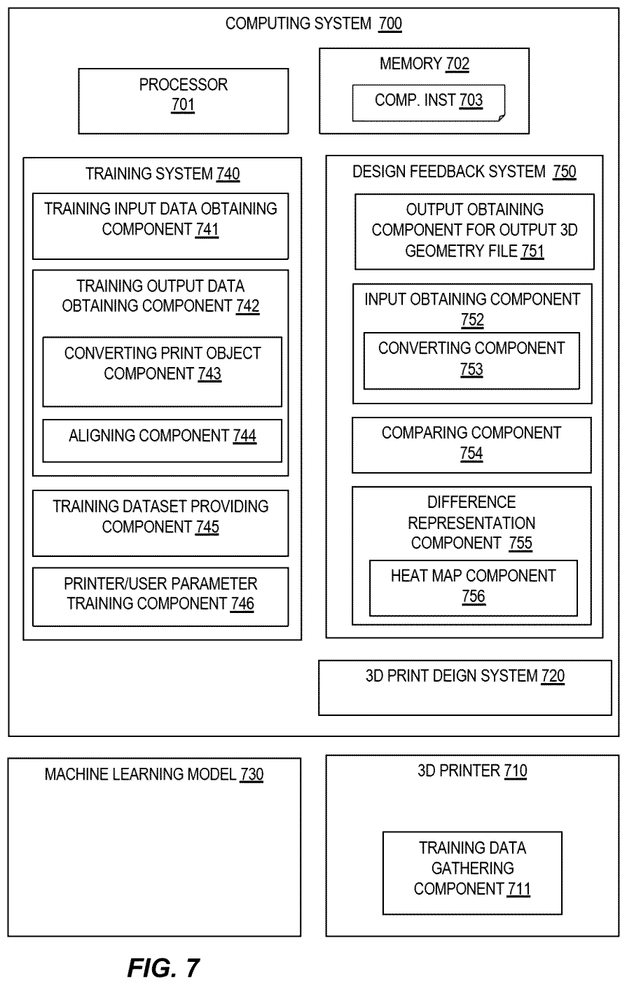

Referring to FIG. 7, a block diagram shows an example embodiment of a system of the disclosure. The system shows 3D printer 710 including a training data gathering component 711 that may be integrated into the 3D printer software or provided in a separate computing system. The system also shows a machine learning model 730 for simulating the 3D printer output as described with reference to FIG. 3. The system also shows a training system 740 for the machine learning model 730.

The system also shows a 3D print design system 720 in the form of design software for producing a 3D geometry file by a designer for printing by the 3D printer 710. The system also shows a design feedback system 750 for providing feedback to a designer based on the output of the machine learning model 730.

The system includes one or more computing system 700. The computing system 700 is shows as supporting the training system 740, the design feedback system 750, and the 3D print design system 720. The training system 740, design feedback system 750, and the 3D print design system may be provided on separate computing systems 700 or integrated on together. For example, the design feedback system 750 may be integrated into the 3D print design system 720. The computing system 700 may include at least one processor 701, a hardware module, or a circuit for executing the functions of the described components which may be software units executing on the at least one processor. Multiple processors running parallel processing threads may be provided enabling parallel processing of some or all of the functions of the components. Memory 702 may be configured to provide computer instructions 703 to the at least one processor 701 to carry out the functionality of the components.

The training system 740 may include the following components. A training input data obtaining component 741 may be provided for obtaining training input data as an input 3D geometry file as input into the 3D printer 710. A training output data obtaining component 742 may be provided for obtaining training output data including a converting print object component 743 may be provided for converting a 3D print output of the 3D printer 710 into an output 3D geometry file of a same file type as the input 3D geometry file and an aligning component 744 may be provided for aligning the output 3D geometry file and the input 3D geometry file. A training dataset providing component 745 may be provided for constructing a training dataset of multiple dataset entries of the combined training input data and training output data for training the simulation model of the 3D printer. A printer/user parameter training component 746 may be provided for obtaining printer parameters and/or user parameters for a printing process generating the 3D print output and including the printer parameters and/or user parameters in the training dataset.

The design feedback system 750 may include the following components. An output obtaining component 751 may be provided for obtaining, in response to processing a current input 3D geometry file in a simulation model for a 3D printer for simulating variations in printing parameters and their effect on the 3D printer output, an output 3D geometry file of a same file type as the input 3D geometry file and aligned to the input 3D geometry file. An input obtaining component 752 may be provided for obtaining the current input 3D geometry file as produced by the designer using the 3D print design system 720. The input obtaining component 752 may include a converting component 753 for, when the output 3D geometry file is of a different resolution to the input 3D geometry file, converting the input 3D geometry file into a software-generated resolution 3D geometry file of the same resolution as the output 3D geometry file. A comparing component 754 may be provided for comparing the input 3D geometry file and the output 3D geometry file from the simulation model to determine differences. A difference representation component 755 may be provided for displaying a representation of the differences to a user. The difference representation component 755 may include a heat-map component 756 for displaying the differences as a heat-map.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

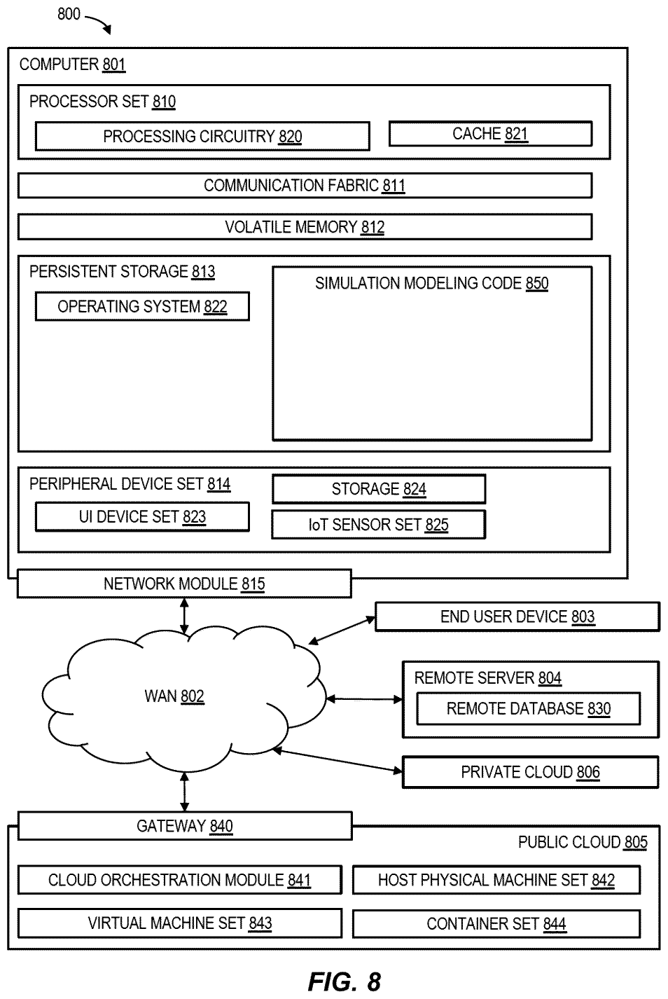

Referring to FIG. 8, computing environment 800 contains an example of an environment for the execution of at least some of the computer code involved in performing the inventive methods, such as 3D printer simulated modeling code 850. In addition to block 850, computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 850, as identified above), peripheral device set 814 (including user interface (UI) device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

COMPUTER 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 8. On the other hand, computer 801 is not required to be in a cloud except to any extent as may be affirmatively indicated.

PROCESSOR SET 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip. ” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 850 in persistent storage 813.

COMMUNICATION FABRIC 811 is the signal conduction path that allows the various components of computer 801 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 812 is any type of volatile memory now known or to be developed in the future. Examples include dynamic type random access memory (RAM) or static type RAM. Typically, volatile memory 812 is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

PERSISTENT STORAGE 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid state storage devices. Operating system 822 may take several forms, such as various known proprietary operating systems or open source Portable Operating System Interface-type operating systems that employ a kernel. The code included in block 850 typically includes at least some of the computer code involved in performing the inventive methods.

PERIPHERAL DEVICE SET 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

NETWORK MODULE 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815.

WAN 802 is any wide area network (for example, the internet) capable of communicating computer data over non-local distances by any technology for communicating computer data, now known or to be developed in the future. In some embodiments, the WAN 802 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

REMOTE SERVER 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

PUBLIC CLOUD 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802.

Some further explanation of virtualized computing environments (VCEs) will now be provided. VCEs can be stored as “images. ”A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Improvements and modifications can be made to the foregoing without departing from the scope of the present invention.

1. A computer-implemented method for training a simulation model of a three-dimensional (3D) printer, said method comprising:
obtaining training input data as an input 3D geometry file as input into the 3D printer;
obtaining training output data by converting a 3D print output of the 3D printer generated in response to the input 3D geometry file into an output 3D geometry file of a same file type as the input 3D geometry file and aligning the output 3D geometry file and the input 3D geometry file; and
constructing a training dataset entry of combined training input data and training output data for training the simulation model of the 3D printer.

2. The method of claim 1, wherein the converting of a 3D print output includes:
photogrammetry converting photographs of the 3D print output into an output 3D geometry file.

3. The method of claim 1, wherein the output 3D geometry file is of a different resolution to the input 3D geometry file and the training dataset is provided for training the simulation model to output the higher resolution 3D geometry file.

4. The method of claim 1, including:
obtaining printer parameters and/or user parameters for a printing process generating the 3D print output and including the printer parameters and/or user parameters in the training dataset.

5. The method of claim 1, including:
obtaining multiple training dataset entries by providing dataset sourcing software at a 3D printer.

6. The method of claim 1, wherein the 3D geometry file describes surface geometry of a 3D object in graph form as a series of linked triangles.

7. A computer-implemented method for modelling simulation of a three-dimensional (3D) printer, said method comprising:
providing a trained simulation deep learning model for a 3D printer for simulating variations in printing parameters and their effect on 3D printer output;
inputting an input 3D geometry file into the trained simulation model;
modeling an embedding representation of the input 3D geometry file;
modeling the printer parameters to output learned embedding;
concatenating the input embedding and the learned embedding; and
outputting an output 3D geometry file aligned to the input 3D geometry file.

8. The method of claim 7, wherein the trained simulation model is a graph neural network (GNN) and the method includes:
encoding the input 3D geometry file using a GNN encoder;
modeling the printer parameters using multi-layer perception to output learned embedding; and
decoding the output 3D geometry file using a GNN decoder.

9. The method of claim 7, including training the simulation model for a 3D printer with training dataset entries of combined training input data and training output data, wherein:
the training input data is obtained as an input 3D geometry file as input into the 3D printer; and
the training output data is obtained by converting a 3D print output of the 3D printer generated in response to the input 3D geometry file into an output 3D geometry file of a same file type as the input 3D geometry file and aligning the output 3D geometry file and the input 3D geometry file.

10. The method of claim 9, wherein the output 3D geometry file is of a higher resolution than the input 3D geometry file based on the training output data in the training datasets.

11. The method of claim 10, wherein a resolution is input as a hyper-parameter of the simulation model.

12. A computer-implemented method for predicting a three-dimensional (3D) printer output, said method comprising:
obtaining, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file;
comparing the input 3D geometry file and the output 3D geometry file from the simulation model to determine differences; and
displaying a representation of the differences to a user.

13. The method of claim 12, wherein the output 3D geometry file is of a different resolution to the input 3D geometry file, and the method includes:
converting the input 3D geometry file into a software-generated resolution 3D geometry file of the same resolution as the output 3D geometry file.

14. The method of claim 12, wherein comparing the input 3D geometry file and the output 3D geometry file includes:
computing a difference between distances of sampled vertices in the aligned input 3D geometry file and the output 3D geometry file.

15. The method of claim 14, including:
converting the computed distances into a heat-map representation by assigning colors to distances.

16. The method of claim 12, including:
providing a trained simulation model for a 3D printer for simulating variations in printing parameters and their effect on the 3D printer output; and
inputting an input 3D geometry file into the simulation model.

17. The method of claim 12, including training the simulation model for a 3D printer with training dataset entries of combined training input data and training output data, wherein:
the training input data is obtained as an input 3D geometry file as input into the 3D printer; and
the training output data is obtained by converting a 3D print output of the 3D printer generated in response to the input 3D geometry file into an output 3D geometry file of a same file type as the input 3D geometry file and aligning the output 3D geometry file and the input 3D geometry file.

18. A trained simulation model for modelling simulation of a three-dimensional (3D) printer, comprising:
an encoder for receiving an input 3D geometry file into the trained simulation model;
a first embedding vector component for embedding a representation of the input 3D geometry file;
a modeling component for receiving printer parameters;
a second embedding vector component for embedding learned printer parameters;
a joint embedding vector component for concatenating the input embedding and the learned embedding; and
a decoder for outputting an output 3D geometry file aligned to the input 3D geometry file.

19. The trained simulation model of claim 18, wherein the trained simulation model is a graph neural network (GNN) and wherein:
the encoder is a GNN encoder;
the modeling component for receiving printer parameters is for modeling the printer parameters using multi-layer perception to output learned embedding; and
the decoder is a GNN decoder.

20. A system for predicting a 3D printer output, comprising:
a processor and a memory configured to provide computer program instructions to the processor to execute a method of:
obtaining, in response to processing an input 3D geometry file in a simulation model for a 3D printer for simulating variations in printing parameters and their effect on the 3D printer output, an output 3D geometry file of a same file type as the input 3D geometry file and aligned to the input 3D geometry file;
comparing the input 3D geometry file and the output 3D geometry file from the simulation model to determine differences; and
displaying a representation of the differences to a user.

21. The system of claim 20, wherein the output 3D geometry file is of a different resolution to the input 3D geometry file, and the method includes:
converting the input 3D geometry file into a software-generated resolution 3D geometry file of the same resolution as the output 3D geometry file.

22. The system of claim 20, wherein comparing the input 3D geometry file and the output 3D geometry file includes:
computing a difference between distances of sampled vertices in the aligned input 3D geometry file and the output 3D geometry file; and
converting the computed distances into a heat-map representation by assigning colors to distances.

23. The system of claim 20, wherein the method includes:
providing a simulation model for a 3D printer for simulating variations in printing parameters and their effect on the 3D printer output;
training the simulation model for a 3D printer with training dataset entries of combined training input data and training output data, wherein:
the training input data is obtained as an input 3D geometry file as input into the 3D printer; and
the training output data is obtained by converting a 3D print output of the 3D printer generated in response to the input 3D geometry file into an output 3D geometry file of a same file type as the input 3D geometry file and aligning the output 3D geometry file and the input 3D geometry file.

24. The system of claim 23, wherein the converting of a 3D print output includes:
photogrammetry conversion of photographs of the 3D print output into an output 3D geometry file.

25. A computer program stored on a computer readable medium and loadable into internal memory of a digital computer, comprising software code portions, when said program is run on a computer, for performing the method steps of claim 1.
